(19) United States
(12) Patent Application Publication
(10) Pub. No.: US 2026/0229421 A1
(43) Pub. Date: Aug. 6, 2026

(54) PUSH BUTTON SWITCH

(71) Applicant: MAKERSAN MAKINA OTOMOTIV SANAYI TICARET ANONIM SIRKETI, Gebze, Kocaeli (TR)

(72) Inventors: Levent ERKOCAK, Gebze (TR); Umit DEMIR, Gebze (TR)

(73) Assignee: MAKERSAN MAKINA OTOMOTIV SANAYI TICARET ANONIM SIRKETI, Gebze, Kocaeli (TR)

(21) Appl. No.: 19/152,711

(22) PCT Filed: Jul. 3, 2024
(86) PCT No.: PCT/TR2024/050757

§ 371 Date: Jul. 31, 2025

(30) Foreign Application Priority Data
Oct. 4, 2023 (TR) 2023/012488

(51) Int. Cl. H01H 13/14; H01H 13/06

(52) U.S. Cl. CPC H01H 13/14; H01H 13/06

(57) ABSTRACT

A push button switch comprising a body; a push button accessible from a first end of the body, comprising a pushing surface, and capable of moving linearly between a resting position and a pushed position within at least a portion of the body; a mounting unit located at a second end of the body; an elastic insulation sleeve enclosing at least a portion of the push button and at least a first end of the body; a springback section which accumulates an elastic potential energy by bending when the push button is moved from the resting position to the pressed position by applying a force on the pushing surface, and which, when the force applied is released, moves the push button from the pushed position to the resting position by means of the accumulated potential energy, and forms at least a portion of the insulation sleeve.

### TECHNICAL FIELD OF THE INVENTION

The present invention relates to a push button switch, in particular to a push button switch that is insulated from external environmental influences.

### BACKGROUND OF THE INVENTION

Push button switches are devices comprising mechanical and electronic components that perform a specific task, e.g. to turn on/off a device, activate a function, or start an operation by applying a pushing force thereon. Push button switches are widely used in a wide range of applications, both indoor and outdoor, including electronics, machinery and consumer products.

The electronic components of the push button switches are so sensitive that they don't permit liquid contact. Therefore, the electronic components of the push button switches, especially those to be used outdoors, should be designed to achieve liquid insulation.

It is also observed that certain extreme outdoor conditions adversely affect the operation of the mechanical components of the push button switches. In particular, external materials such as oil and fine sand may penetrate into the mechanical components. If this happens, it changes the pressing feeling of the push button switch, which negatively affects the use of the push button switches by the user. In some instances, solidified/frozen oil or sand grains may cause the push button switch to get jammed, causing it to not work or to be stuck in a certain function. If a push button switch, especially used in construction machinery and heavy industry, fails to work or gets stuck, this may cause loss of life and property.

In view of the shortcomings of the prior art push button switches, there is a need in the art for a push button switch that is insulated from the effects of the external environment.

### Objects of the Invention

A main object of the present invention is to provide an insulated push button switch which is free from the effects of external materials, in particular oil and sand.

Another object of the invention is to provide a push button switch comprising a plurality of resilient members for the return movement of the push button, thereby increasing safety and security.

Yet another object of the invention is to provide a push button switch with an improved pressing feeling, which can maintain the pressing feeling for a long time and thus increase safety and security.

### DETAILED DESCRIPTION OF THE INVENTION

A push button switch that is implemented to achieve the object of the present invention is illustrated in the accompanying drawings, wherein the details of the invention should be evaluated in view of the entire specification. Wherein;

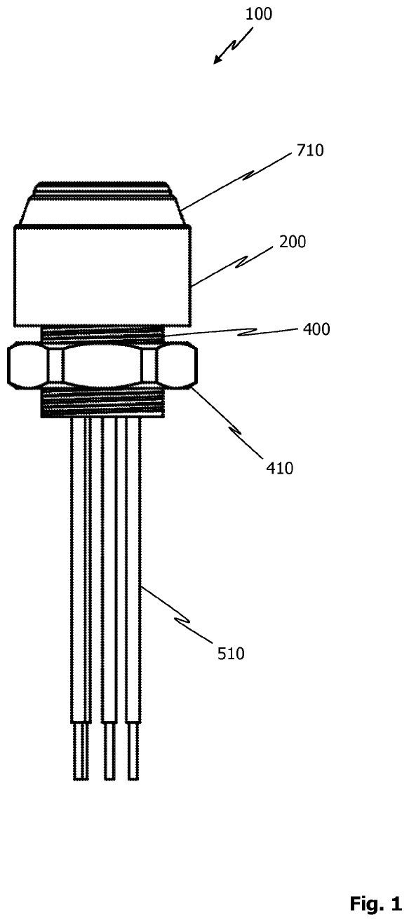

FIG. 1 is a schematic side view of a push button switch in an exemplary embodiment of the invention.

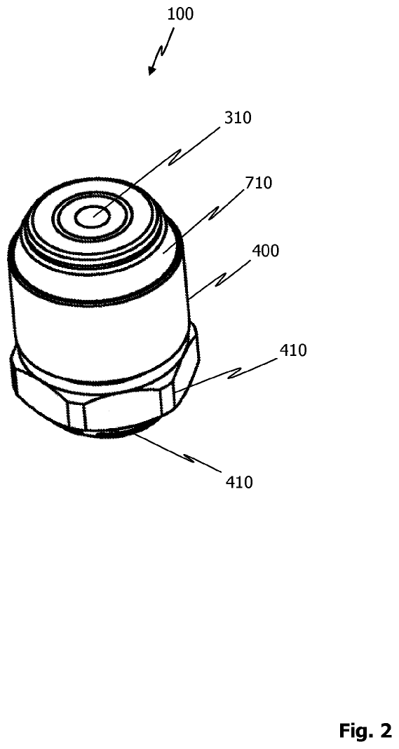

FIG. 2 is a perspective schematic view of a push button switch in an exemplary embodiment of the invention.

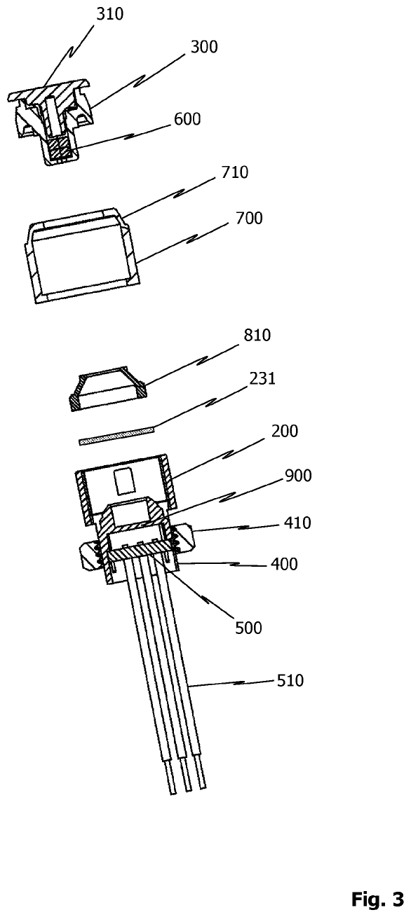

FIG. 3 is an exploded schematic view of a push button switch in an exemplary embodiment of the invention.

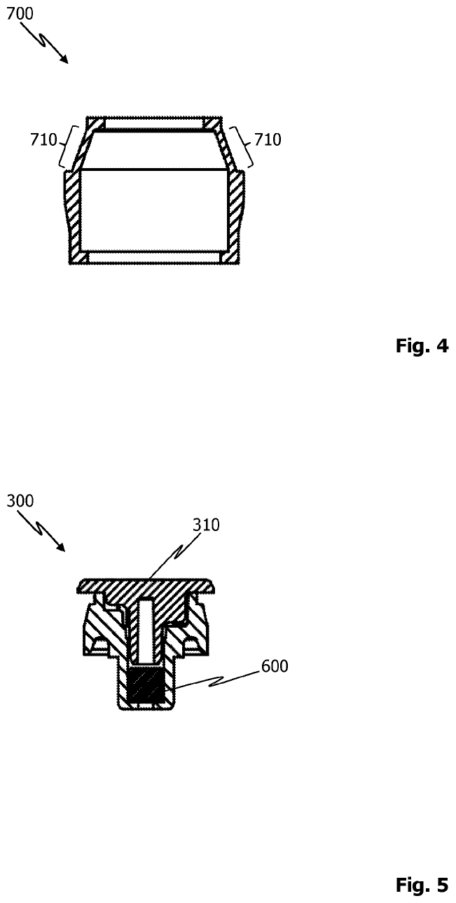

FIG. 4 is a schematic view of an insulation sleeve in an exemplary embodiment of the invention.

FIG. 5 is a schematic view of a push button switch in an exemplary embodiment of the invention.

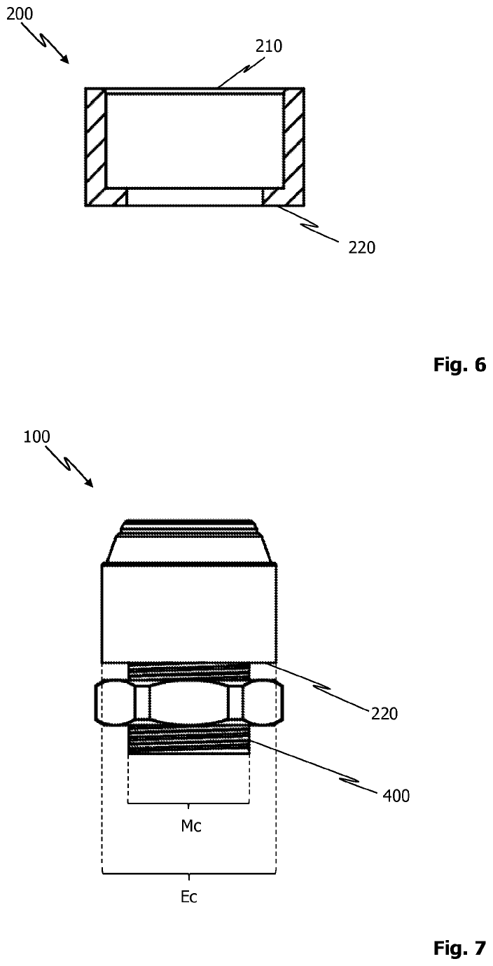

FIG. 6 is a schematic view of a body in an exemplary embodiment of the invention.

FIG. 7 is a schematic side view of a push button switch in an exemplary embodiment of the invention, comprising an insulation sleeve enclosing at least a portion of a second end.

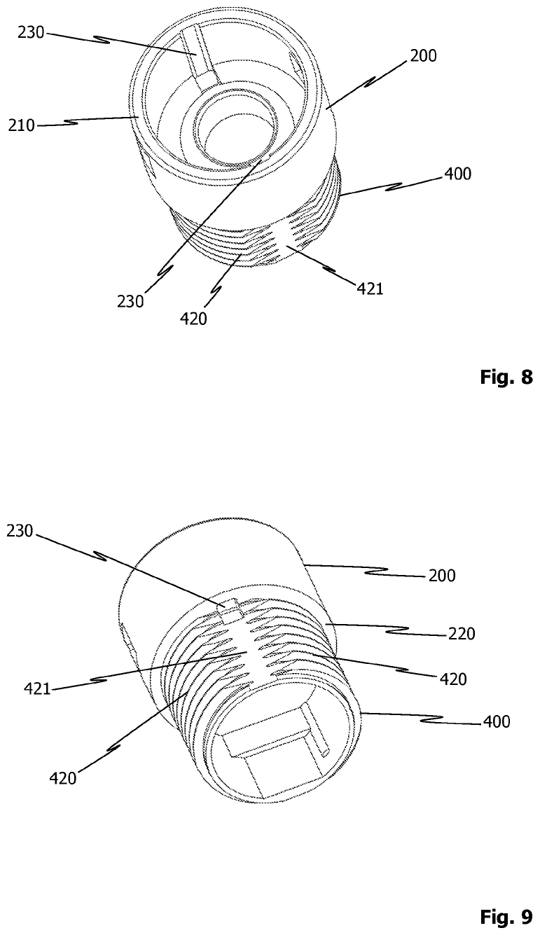

FIG. 8 is a schematic top view of a body comprising a mounting unit in an exemplary embodiment of the invention.

FIG. 9 is a schematic bottom view of the body comprising a mounting unit in an exemplary embodiment of the invention.

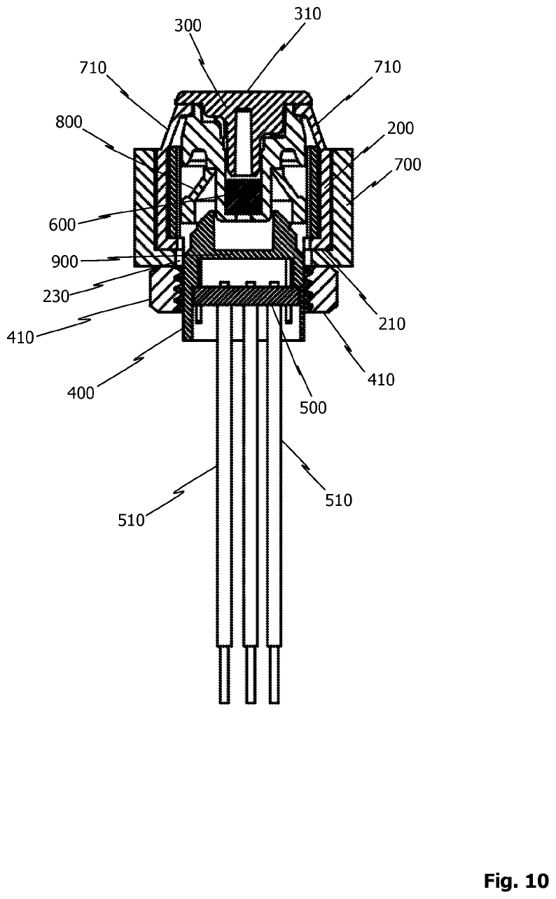

FIG. 10 is a side schematic cross-sectional view of a push button switch in an exemplary embodiment of the invention, comprising a push button in a resting position.

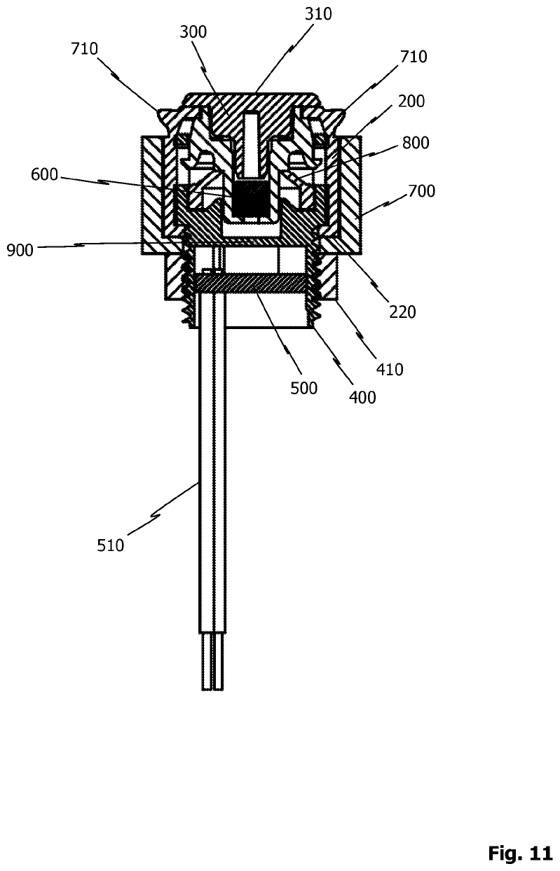

FIG. 11 is a side schematic cross-sectional view of a push button switch in an exemplary embodiment of the invention, comprising a push button in a pushed position.

### THE REFERENCE NUMBERS USED IN THE DRAWINGS ARE GIVEN BELOW

100. Push button switch
200. Body
   210. First end
   220. Second end
   230. Air channel
      231. Filter
300. Push button
   310. Pushing surface
400. Mounting unit
   410. Nut
   420. Bolt threads
   421. Air gap
500. Electronic member
   510. Connection terminal
600. Magnetic member
700. Insulation sleeve
   710. Springback section
800. Spring member
900. Insulation barrier
Ec. Cross-sectional area of the second end
Mc. Cross-sectional area of the mounting unit

The invention relates to a push button switch (100) which can continue its operation without being affected by external materials such as snow, rain, dust, sand, etc. The push button switch (100) is used herein to mean a circuit member that generates an electrical/electronic signal and/or turns on/off a circuit by applying a pushing force thereon.

The push button switch (100) comprises a body (200); a push button (300) accessible from a first end (210) of the body (200), comprising a pushing surface (310), and capable of moving linearly between a resting position and a pushed position within at least a portion of the body (200); a mounting unit (400) located at a second end (220) of the body (200); an electronic member (500) adapted to generate at least a signal when exposed to a magnetic field exceeding a selected magnetic field strength; a magnetic member (600) that is capable of moving linearly together with the push button (300), and which, when the push button (300) is in the pushed position, is located closer to the electronic member (500) than the resting position.

The push button switch (100) also comprises an elastic insulation sleeve (700) enclosing at least a portion of the push button (300) and at least a first end (210) of the body (200) in order to insulate the first end (210); a springback section (710) which accumulates an elastic potential energy by being bending when the push button (300) is moved from the resting position to the pushed position by applying a force on the pushing surface (310), and which, when the force applied is released, moves the push button (300) from the pushed position to the resting position by means of the accumulated potential energy, and forms at least a portion of the insulation sleeve (700).

The push button (300) is situated at the first end (210) of the body (200), and at least a portion of the push button (300) is located inside the body (200). The body (200) may have a tubular form, and preferably has a cylindrical form. It is free to move in the body (200) up and down in a linear direction. When a force is applied to the pushing surface (310) of the push button (300), for example when an operator presses against the pushing surface (310) with his finger, the push button (300) moves into the body (200). When no external force is applied on the pushing surface (310), for example when the operator does not press against the pushing surface (310) with his/her finger, the position of the push button (300) in the body (200) is the resting position (see FIG. 1 and FIG. 8). When an external force is applied on the pushing surface (310), for example when the operator presses against the pushing surface (310) with his/her finger, the position of the push button (300) in the body (200) is the pushed position (see FIG. 9). In the resting position, the push button (300) may be fully located in the body (200) together with the pushing surface (310). In a preferred embodiment of the invention, in the resting position, the push button (300) is located inside the body (200) such that the pushing surface (310) is outside the body (200). The mounting unit (400) is situated at the second end (220), which is the opposite end of the first end (210). The mounting unit (400) is to mount the push button switch (100) to a location where it is to be used, e.g. a device, a device chassis, a motor vehicle, etc. The push button switch (100) comprises an electronic member (500) adapted to generate at least a signal when exposed to a magnetic field exceeding the selected magnetic field strength. The electronic member (500) may be in the form of a printed circuit board (PCB). The electronic member (500) may also generate different signals depending on the duration of exposure to the magnetic field exceeding the selected magnetic field strength. The signal generated can be used to turn on/off a circuit and/or to start/stop a feature of a device. The push button switch (100) comprises a magnetic member (600) that is capable of moving linearly together with the push button (300). The magnetic member (600) may be a natural magnet, or an artificial magnet such as NdFeB, Sm-Co, Sm-Fe, samarium, cobalt, and neodymium. The magnetic member (600) may be integral with the push button (300) and is located at the opposite end of the pushing surface (310) of the push button (300). When the push button (300) is in the pushed position, the magnetic member (600) is adapted/positioned to be located closer to the electronic member (500) than the resting position. Therefore, the electronic member (500) is located opposite to the push button (300). The electronic member (500) may be located at the second end (220) of the body (200) or in the mounting unit (400). When the push button (300) is in the resting position, the magnetic member (600) is positioned away from the electronic member (500) such that a signal is generated in the electronic member (500). When the push button (300) is in the resting position, the magnetic field strength generated by the magnetic member (600) is less than the selected magnetic field strength. When an external force is applied on the pushing surface (310) of the push button (300), the push button (300) moves with the magnetic member (600) into the body (200) and is switched into the pushed position. When the push button (300) is in the pushed position, the magnetic member (600) is positioned close to the electronic member (500) such that at least a signal is generated in the electronic member (500). When the push button (300) is in the pushed position, the magnetic field strength generated by the magnetic member (600) is above the selected magnetic field strength. Thus, when an external force is applied on the pushing surface (310) of the push button (300), the electronic member (500) generates at least a signal.

The push button switch (100) comprises an insulation sleeve (700) enclosing at least a portion of the push button (300) and at least a first end (210) of the body (200). The insulation sleeve (700) may be made of rubber, elastic polymers, or silicone. Due to its long service life, a silicone insulation sleeve (700) is preferable. Since the push button (300) is movable relative to the body (200), there must be a gap between the body (200) and the push button (300). If the gap is open to the external environment, such materials as water, salt water, oil, dust, sand may penetrate into the gap. The materials may close the gap and block the movement of the push button (300). Sometimes, the push button (300) may be stuck in the resting position or in the pushed position. This presents a significant risk of security. The gap between the body (200) and the push button (300) is physically insulated from outside by means of the insulation sleeve (700). This eliminates the risk that such materials as water, salt water, oil, dust, sand, etc. that may settle between the said gap may prevent the linear movement of the push button (300). In a preferred embodiment of the invention, the insulation sleeve (700) encloses the entire pushing surface (310) (see FIG. 2 and FIG. 4).

The insulation sleeve (700) comprises a springback section (710). The springback section (710) forms at least a portion of the insulation sleeve (700). When the push button (300) is switched from the resting position to the pushed position by applying an external force on the pushing surface (310), the springback section (710) bends and accumulates an elastic potential energy. When the external force applied on the pushing surface (310) is released, the springback section (710) moves the push button (300) from the pushed position to the resting position by means of the potential energy accumulated thereon. The springback section (710) acts as a spring that moves the push button (300) from the pushed position to the resting position. The elastic potential energy to be accumulated by bending the springback section (710) generates a rebound force that moves the push button (300) from the pushed position to the resting position. In the embodiment with a cylindrical body (200), the insulation sleeve (700) also has a cylindrical from. The springback section (710) is in the form of a ring forming a cross-section of the cylindrical insulation sleeve (700). The elastic potential energy to be accumulated by bending the springback section (710) depends on the elastic constant, thickness and wall thickness of the springback section (710). Therefore, the elastic constant, thickness and wall thickness of the springback section (710) may be adjusted in accordance with the elastic potential energy to be accumulated. The wall thickness of the springback section (710) may be greater than that of the insulation sleeve (700). Thus, the elastic potential energy that can be accumulated in the springback section (710) may be increased without using extra material for the insulation sleeve (700). The insulation sleeve (700) and thus the springback section (710) may be made of a shape memory material.

In an embodiment of the invention, the push button switch (100) comprises at least a flexible spring member (800) located between the push button (300) and the electronic member (500) in the body (200), which accumulates an elastic potential energy by being bending when the push button (300) is moved from the resting position to the pushed position by applying a force on the pushing surface (310), and which moves the push button (300) from the pushed position to the resting position by means of the accumulated potential energy when the force applied is released. The spring member (800) may be made of rubber, elastic polymers, or silicone. Due to its long service life, a silicone spring member (800) is preferable. In the preferred embodiment of the invention, the spring member (800) may be in cylindrical form, in particular conical form (see FIG. 3). The conical spring member (800) bends into itself. This eliminates the need to create a discharge section in the body (200) for the bending part of the spring member (800). The spring member (800) performs the same function as the springback section (710). When an external force is applied on the pushing surface (310) to move the push button (300) from the resting position to the pushed position, the spring member (800) as well as the springback section (710) are bent and accumulate an elastic potential energy. When the external force applied on the pushing surface (310) is released, the spring member (800) and the springback section (710) moves the push button (300) from the pushed position to the resting position by means of the potential energy accumulated thereon. The spring member (800), similar to the springback section (710), acts as a spring to move the push button (300) from the pushed position to the resting position. The elastic potential energy to be accumulated by bending the spring member (800) as well as the springback section (710) generates a rebound force to move the push button (300) from the pushed position to the resting position. The elastic potential energy to be accumulated by bending the spring member (800) depends on the elastic constant, thickness and wall thickness of the spring member (800). Therefore, the elastic constant, thickness and wall thickness of the spring member (800) may be adjusted according to the elastic potential energy to be accumulated. The spring member (800) may be made of a shape memory material. In this embodiment, the push button (300) is moved from the pushed position to the resting position by the springback section (710) and the spring member (800). However, both the springback section (710) and the spring member (800) are adapted to accumulate elastic potential energy such that they may alone move the push button (300) from the pushed position to the resting position. Thus, if a fault occurs in either the springback section (710) or in the spring member (800) (e.g. in case a tear occurs, or in case elasticity is lost over time and a sufficiently large amount of elastic potential energy cannot be accumulated), the other one will safely move the push button (300) from the pushed position to the resting position. This provides a dual safety and security. When such fault is experienced, the force required to move the push button (300) from the resting position to the pushed position will be reduced. Such reduction in the required force can be easily detected by the operator. The detection thereof indicates that there is a fault in the springback section (710) or spring member (800) and that the push button switch (100) is not operating properly. This allows the operator to replace the push button switch (100) before the function of the push button switch (100) is completely lost.

In an embodiment of the invention, the push button switch (100) comprises an insulation barrier (900) located between the first end (210) and the electronic member (500), insulating the electronic member (500) from the first end (210). In this embodiment, the electronic member (500) is protected against external materials such as water, salt water, oil, dust, sand, etc. that may come from the first end (210). When the electronic member (500) which may be particularly sensitive to liquid contact is physically insulated, this guarantees a discontinuous and proper operation of the electronic member (500). A tear in the insulation sleeve (700), and in particular in the springback section (710), may allow said external materials to penetrate into the gap between the body (200) and the push button (300). If these materials, in particular liquids, reach the electronic member (500), this may cause damage to the electronic member (500). The insulation barrier (900) prevents any external material from reaching the electronic member (500) from the first end (210), in particular from the gap between the body (200) and the push button (300). The insulation barrier (900) may be in the form of an epoxy filler. The insulation barrier (900) may be an integral part of the body (200). In this embodiment, a section of the body (200) forms an H-shape, and the center line of the H-shape acts as the insulation barrier (900).

The term insulation in this application describes a physical insulation. Herein, magnetic, radioactive, heat, light and sound insulation are not intended.

In an embodiment of the invention, the push button switch (100) comprises a cross-sectional area (Ec) of the second end (220) being larger than a cross-sectional area (Mc) of the mounting unit (400) (see FIG. 7), and an insulation sleeve (700) enclosing at least a portion of the second end (220). The insulation sleeve (700) is made of an elastic material and is tightly wrapped around at least a part of the push button (300) and at least the first end (210) of the body (200), thereby maintaining its position throughout the linear movement of the push button (300). In this embodiment, the portion of the insulation sleeve (700) enclosing the second end (220) is compressed between the second end (220) and the mounting structure (e.g. the chassis of the device) upon mounting. This additionally guarantees that the insulation sleeve (700) remains in the position where it encloses the push button (300) and the body (200).

In an embodiment of the invention, the push button switch (100) comprises at least one air channel (230) extending from inside of the body (200) towards the second end (220). As a result of the physical insulation by the insulation sleeve (700), a closed volume is formed in the body (200). The push button (300) moves into the body (200) when being moved from the released position to the pushed position. With this movement, the closed volume in the body (200) is narrowed and the air in the body (200) is compressed. Such compression does not prevent the operation of the push button switch (100), i.e. the linear movement of the push button (300). Moving the push button (300) from the released position to the pushed position is usually realized by the operator applying an external force on the pushing surface (310) with his finger. Said air compression may negatively affect the tactile sensation, and the click sensation of operator while applying external force. To maintain this sensation, the air in the body (200) must be discharged. With the air channel (230), the air in the body (200) is discharged from a part of the body (200), which is not enclosed by the insulation sleeve (700). Similarly, when the external force applied on the pushing surface (310) is released, air passes into the body (200) through the air channel (230) when the push button (300) is being moved from the pushed position to the released position. The air discharge is preferably realized through the second end (220). The air channel (230) is adapted to be positioned so as not to break the physical insulation performed by the insulation sleeve (700) and/or the insulation barrier (900). The air channel (230) may be in a tubular form. In a variant of this embodiment, the push button switch (100) comprises at least one filter (231) which covers at least a portion of the air channel (230) and is impermeable to liquid and dust. Although the opening of the air channel (230) is adapted so that the push button switch (100) is located in an enclosed part of the structure in which it is to be mounted, the filter (231) prevents any external material from passing through the air channel (230) into the body (200).

In an embodiment of the invention, the push button switch (100) comprises the push button (300) wherein at least a portion of the pushing surface (310) is transparent, and the electronic member (500) having a light source. The light generated by the light source is visible through the transparent pushing surface (310). In this embodiment, the state of the push button switch (100), i.e. the signal generated by the electronic member (500), is visually indicated by a light on the pushing surface (310). Different colors of light can be generated by the light source for different signals that can be generated. The pushing surface (310) may include symbols indicating the state of the push button switch (100).

In an embodiment of the invention, the push button switch (100) comprises the mounting unit (400) in the form of a bolt, preferably in the form of a hollow bolt. In a variant of this embodiment, the push button switch (100) comprises a nut (410) suitable for engaging with the mounting unit (400) in the bolt form. The push button switch (100) can be mounted by tightening a chassis/panel between the second end (220) and the nut (410).

In an embodiment of the invention, the push button switch (100) comprises at least one connection terminal (510) for providing an electrical connection to the electronic member (500). This facilitates the electrical/electronic connections during mounting of the push button switch (100). In a variant of this embodiment, the connection terminals (510) are passed through the mounting unit (400) which is in the form of a hollow bolt. This embodiment provides a suitable outlet for the connection terminals (510) and protects at least a part of the connection terminals (510) from physical influences by means of the hollow bolt-shaped mounting unit (400) through which they pass.

In an embodiment of the invention, the push button switch (100) comprises an air gap (421) facing an air channel (230) at the second end (220), extending through at least a portion of the bolt-shaped mounting unit (400), and which intersects the bolt threads (420) substantially perpendicularly (see FIG. 8 and FIG. 9). The air gap (421) has a structure that disrupts the continuity of the bolt threads (420). In this embodiment, an end of the air channel (230) forms an opening in the second end (220) (see FIG. 9). Even with a nut (410) on the bolt-shaped mounting unit (400), the thread openings between the bolt threads (420) only allow a certain amount of air to pass therethrough. A more efficient air input and output into the air channel (230) through the opening at the second end (220) via the air gap (421) is achieved.

1. A push button switch comprising a body; a push button accessible from a first end of the body, comprising a pushing surface and capable of moving linearly between a resting position and a pushed position within at least a portion of the body; a mounting unit located at a second end of the body; an electronic member adapted to generate at least a signal when exposed to a magnetic field exceeding a selected magnetic field strength; a magnetic member that is capable of moving linearly together with the push button, and which, when the push button is in the pushed position, is located closer to the electronic member than the resting position, characterized by an elastic insulation sleeve enclosing at least a portion of the push button and at least a first end of the body in order to insulate the first end; a springback section which accumulates an elastic potential energy by being bended when the push button is moved from the resting position to the pushed position by applying a force on the pushing surface, and which, when the force applied is released, moves the push button from the pushed position to the resting position by means of the accumulated potential energy, and forms at least a portion of the insulation sleeve.

2. A push button switch according to claim 1, comprising at least a flexible spring member located between the push button and the electronic member in the body, which accumulates an elastic potential energy by being bended when the push button is moved from the resting position to the pushed position by applying a force on the pushing surface, and which moves the push button from the pushed position to the resting position by means of the accumulated potential energy when the force applied is released.

3. A push button switch according to claim 1, comprising an insulation barrier located between the first end and the electronic member, insulating the electronic member from the first end.

4. A push button switch according to claim 1, comprising a cross-sectional area (Ec) of the second end being larger than a cross-sectional area (Mc) of the mounting unit, and the insulation sleeve enclosing at least a portion of the second end.

5. A push button switch according to claim 1, comprising at least one air channel extending from inside of the body towards the second end.

6. A push button switch according to claim 5, comprising at least one filter which covers at least a portion of the air channel and is impermeable to liquid and dust.

7. A push button switch according to claim 1, comprising the push button wherein at least a portion of the pushing surface is transparent; and the electronic member having a light source.

8. A push button switch according to claim 1, comprising the mounting unit in the form of a bolt.

9. A push button switch according to claim 8, comprising a nut suitable for engaging with the mounting unit in the bolt form.

10. A push button switch according to claim 1, comprising at least one connection terminal for providing an electrical connection to the electronic member.

11. A push button switch according to claim 1, comprising the mounting unit in the form of a hollow bolt through which the connection terminals are passed.

12. A push button switch according to claim 5, comprising an air gap facing an air channel at the second end, extending through at least a portion of the bolt-shaped mounting unit, and which intersects the bolt threads substantially perpendicularly.
